(19) United States
(12) Patent Application Publication
(10) Pub. No.: US 2008/0043406 A1
(43) Pub. Date: Feb. 21, 2008

(54) PORTABLE COMPUTER SECURITY DEVICE THAT INCLUDES A CLIP

(75) Inventor: Noah L. Anglin, San Jose, CA (US)

Correspondence Address: SCHWEGMAN, LUNDBERG & WOESSNER, P.A., P.O. BOX 2938, MINNEAPOLIS, MN, 55402, US

(73) Assignee: Secure Computing Corporation

(21) Appl. No.: 11/464,953

(22) Filed: Aug. 16, 2006

(51) Int. Cl. H05K 5/00

(52) U.S. Cl. 361/679

(57) ABSTRACT

The present invention relates to a to a portable computer security device that includes a clip. The portable computer security device is readily attached to another object so that it is easier to keep track of the portable computer security device. The portable computer security device includes a housing that has an integrated circuit and an LCD positioned within the housing. The integrated circuit generates random numbers for display on the LCD such that the random numbers are used to provide access to a computer system. The portable computer security device further includes a closing member. A flat spring engages the housing and the closing member such that the flat spring biases the closing member against the housing. In some embodiments, the flat spring, the closing member and the housing form a carbineer style clip so that the portable computer security device may be readily attached to an object.

### FIELD

The present invention relates to a portable computer security device, and in particular to a portable computer security device that includes a clip.

### BACKGROUND

Portable computer security devices are commonly used to provide a point for policy enforcement and reporting as it relates to computer system security. The use of portable computer security devices also permits anywhere, anytime remote access to applications, data and networks.

Most portable security devices are used to provide convenient, secure wireless and wired LAN access for individuals such as employees, contractors and guests. A portable computer security device may serve as a reliable mechanism to enable configuration compliance while ensuring that every end-point device adheres to a security policy.

The endpoint security that is enabled by portable computer security devices ensures that only properly configured end-point devices can access the network. Portable computer security devices serve as a vital component to a complete identity and access management strategy for computing systems.

Manufacturers are constantly trying to make portable computer security devices as small, portable, cheap and adaptable as possible. One of the drawbacks with existing portable security devices is that they are often easily misplaced due to their small size.

There is a need for a portable computer security device that is able to be readily attached to another object so that it is easier to keep track of the portable computer security device. The portable computer security device should incorporate the features, quality and styling of existing portable computer security devices without sacrificing the ability of the portable computer security device to be readily attached to another object.

### SUMMARY OF THE INVENTION

The present invention relates to a to a portable computer security device that includes a clip. The portable computer security device is readily attached to another object so that it is easier to keep track of the portable computer security device.

The portable computer security device includes a housing that has an integrated circuit and a liquid crystal display (hereafter LCD) positioned within the housing. The integrated circuit generates random numbers for display on the LCD such that the random numbers are used to provide access to a computer system.

The portable computer security device further includes a closing member. A flat spring engages the housing and the closing member such that the flat spring biases the closing member against the housing. In some embodiments, the flat spring, the closing member and the housing form a carbineer style clip so that the portable computer security device may be readily attached to an object.

The purposes and features of the present invention will be set forth in the description that follows. Additional features of the invention may be realized and attained by the product and processes particularly pointed out in the written description and claims hereof, as well as from the appended drawings.

It is to be understood that both the foregoing general description and the following detailed description are exemplary and are intended to provide further explanation of the invention claimed. The accompanying drawings, which are incorporated in and constitute part of this specification, are included to illustrate and provide a further understanding of the invention.

### BRIEF DESCRIPTION OF THE DRAWINGS

The present invention will be more fully understood, and further features will become apparent, when reference is made to the following detailed description and the accompanying drawings. The drawings are merely representative and are not intended to limit the scope of the claims. Like parts depicted in the drawings are referred to by the same reference numerals.

FIG. 1 is a perspective view of a portable computer security device.

FIG. 2 is an enlarged side view illustrating a portion of the portable computer security device shown in FIG. 1.

FIG. 3 is an enlarged perspective view of a flat spring and closing member that are illustrated in the portable computer security device shown in FIGS. 1 and 2.

FIG. 4 is an electrical schematic of an example integrated circuit that may be used in the portable computer security device of FIG. 1.

### DETAILED DESCRIPTION OF THE INVENTION

The following detailed description references the accompanying drawings which show some example embodiments of the invention. These example embodiments are described in sufficient detail to enable those skilled in the art to practice the invention. It is to be understood that other embodiments may be utilized, or structural changes made, such that the detailed description should not be considered as limiting the scope of the claims.

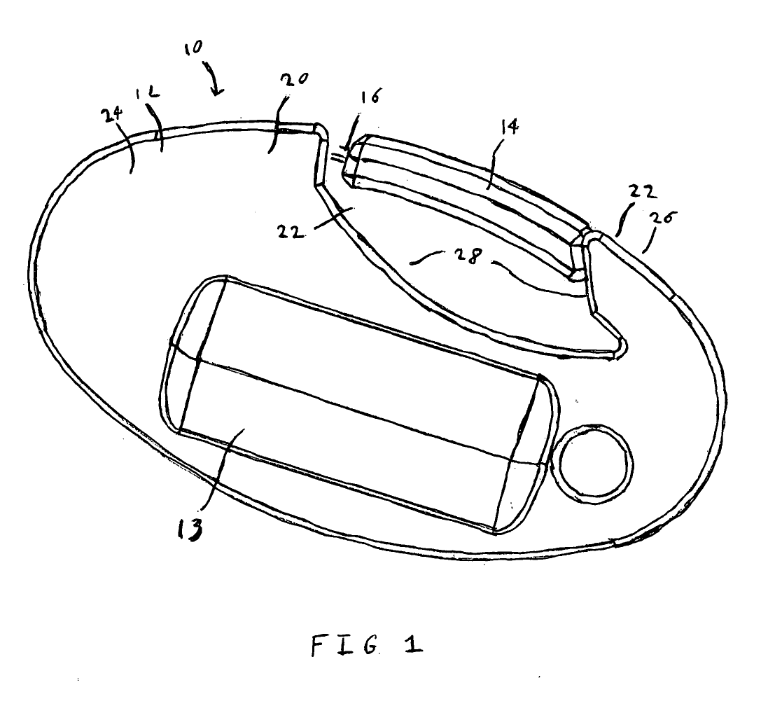

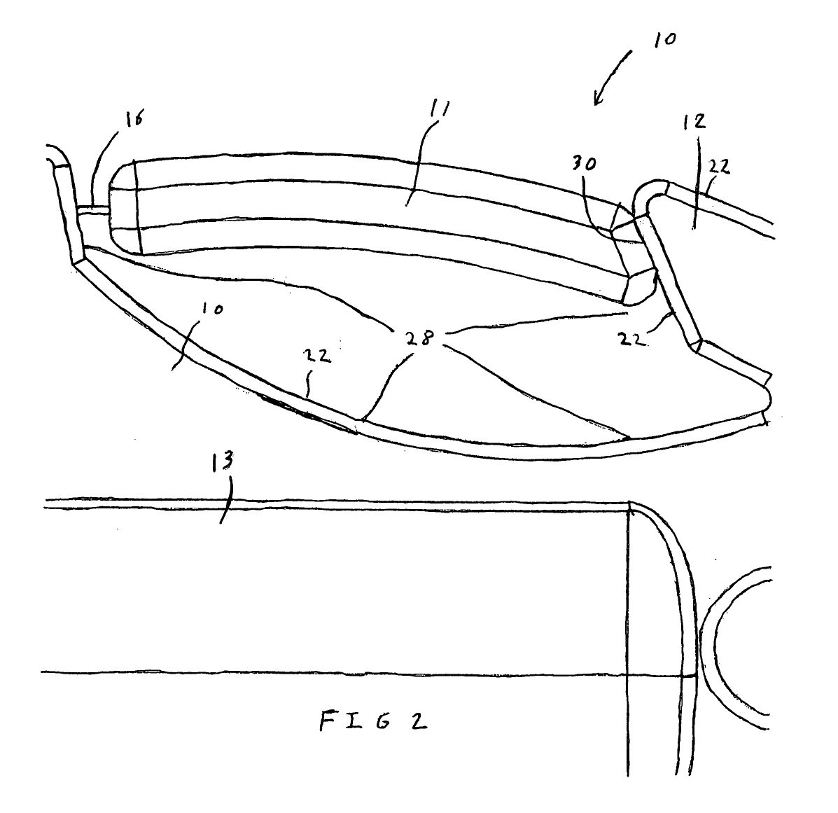

FIGS. 1 and 2 illustrate an example portable computer security device 10. The portable computer security device 10 includes a housing 12 with an integrated circuit 11 (not visible in FIGS. 1 and 2) and an LCD 13 positioned within the housing 12.

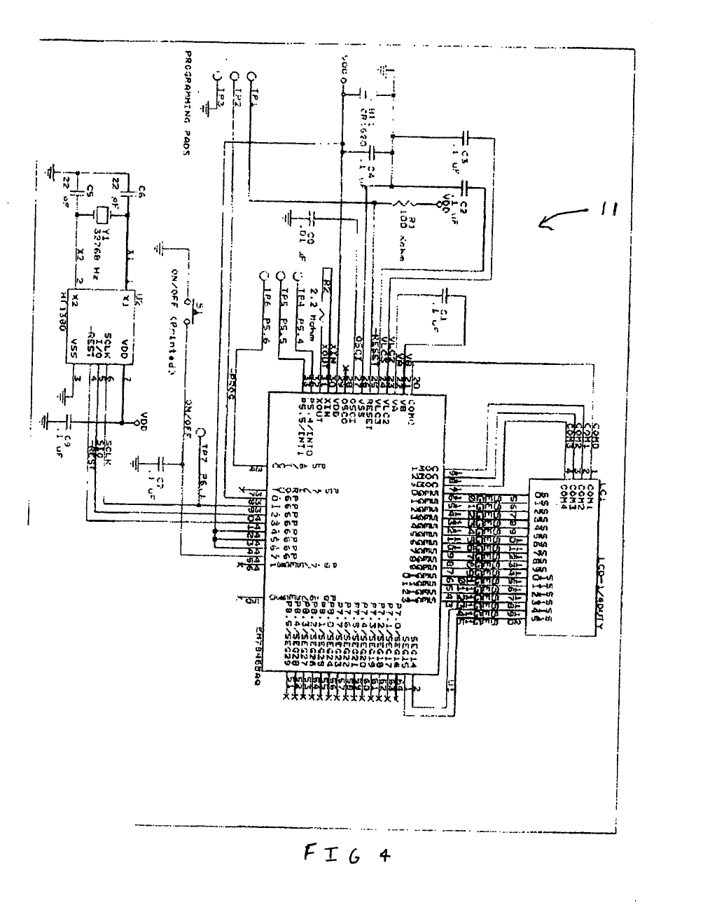

An example integrated circuit 11 is shown in FIG. 4. The integrated circuit 11 generates random numbers for display on the LCD 13 such that the random numbers are used to provide access to a computer system. It should be noted that the random numbers may be generated in an event synchronous mode or a timed synchronous mode.

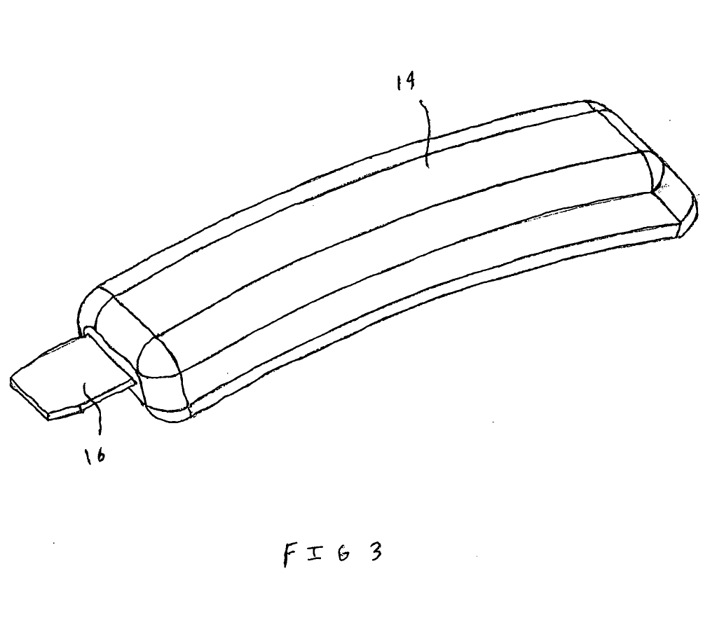

The portable computer security device 10 further includes a closing member 14 (see FIG. 3). A flat spring 16 engages the housing 12 and the closing member 14 such that the flat spring 16 biases the closing member 14 against the housing 12.

In some embodiments, the flat spring 16, the closing member 14 and the housing 12 form a carbineer style clip so that the portable computer security device 10 may be readily attached to an object. In addition, the flat spring 16 may be embedded in the housing 12 and/or the closing member 14.

In the example embodiment that is illustrated in FIGS. 1-3, the closing member 14 is arc-shaped although other shapes are contemplated for the closing member 14. The size and shape of the closing member 14 will depend in large part on the size and shape of the rest of the portable computer security device 10.

In some embodiments, the flat spring 16 may be ultrasonically inserted into the housing 12 and/or the closing member 14. It should be noted that the flat spring 16 may be attached to the housing 12 and/or the closing member 14 in any manner that promotes biasing the closing member 14 against the housing 12.

In other example embodiments, the flat spring 16, the closing member 14 and/or the housing 12 may be formed as part of the same mold such that the flat spring 16, the closing member 14 and/or the housing 12 are integral with one another. The method of attachment between the flat spring 16 and the housing 12 or closing member 14 will depend in large part on the materials that are used to form the flat spring 16, the closing member 14 and the housing 12.

As an example, the flat spring 16 may be formed of tempered spring steel. However, the type of material that is chosen for the flat spring 16 will depend on the size and shape of the housing 12 and the closing member 14 as well as the amount of biasing force that is desired to maintain the closing member 14 against the housing 12.

In the example embodiment that is illustrated in FIGS. 1-2, the housing 12 includes a first surface 20, a second surface (not visible in FIGS. 1 and 2) and a lateral edge 22 that joins the first surface 20 and the second surface. As shown most clearly in FIG. 2, the flat spring 16 extends into the lateral edge 22 of the housing 12. In addition, the closing member 14 engages the lateral edge 22 of the housing 12.

In some embodiments, the housing 12 includes a cover 24 and a base 26 (only partially visible in FIG. 1) such that the cover 24 is secured to the base 26 to form the housing 12. Example materials for the cover 24 and the base 26 include metal and plastic.

The cover 24 may be attached to the base 26 in any manner that is known now or discovered in the future. As an example, the cover 24 may be secured to the base 26 using an adhesive.

The type of attachment between the cover 24 and the base 26 will depend in part on the structural design of the cover 24 and the base 26 (among other factors). In the example embodiment that is illustrated in FIG. 1, the lateral edge 22 of the housing 12 is part of the base 26, although embodiments are contemplated where the lateral edge 22 is part of the cover 24.

In some embodiments, the lateral edge 22 of the housing 12 may extend into the first surface 20 and the second surface of the housing 12 to form an indentation 28 in the housing 12. It should be noted that the size and shape of the indentation 28 will depend in part on the size and shape of the closing member 14 and the overall shape of the portable computer security device 10.

As shown most clearly in FIG. 2, the flat spring 16 extends into one portion of the lateral edge 22 and the closing member 14 engages another portion of the lateral edge 22 such that the flat spring 16 and the closing member 14 extend across the indentation 28 in the housing 12. In the example embodiment that is illustrated in FIGS. 1-2, the flat spring 16 extends into the lateral edge 22 of the housing 12 within the indentation 28 in the housing 12. In addition, the closing member 14 engages the lateral edge 22 of the housing 12 within the indentation 28 in the housing 12.

The portable computer security device 10 is attached to an object (not shown) by depressing the closing member 14 into the indentation 28. Once the object is inserted into the indentation 28, the closing member 14 is released and the flat spring 16 biases the closing member 14 back into engagement with the lateral edge 22 of the housing 12. The object is then secured within the indentation 28 by the lateral edge 22 of the housing 12 and the closing member 14.

In some embodiments, the closing member 14 includes a planar surface 30 (see FIG. 2) that engages a planar section of the lateral edge 22 on the housing 12. It should be noted that the relative sizes and shapes of the planar surface 30 and the lateral edge 22 will depend in part on the size and shape of (i) the closing member 14; (ii) the indentation 28; and (ii) the overall shape of the portable computer security device 10.

The portable computer security devices 10 described herein are readily attached to another object. The ability of the portable computer security devices 10 to be readily attached to another object makes it is easier to keep track of the portable computer security devices.

While the invention has been described in detail with respect to the specific aspects thereof, it will be appreciated that those skilled in the art, upon attaining an understanding of the foregoing, may readily conceive of alterations to, variations of, and equivalents to these aspects which fall within the spirit and scope of the present invention, which should be assessed accordingly to that of the appended claims.

I claim:

1. A portable computer security device comprising:
a housing;
a LCD within the housing;
an integrated circuit within the housing, the integrated circuit generating random numbers for display on the LCD such that the random numbers are used to provide access to a computer system;
a closing member; and
a flat spring engaging the housing and the closing member such that the flat spring biases the closing member against the housing.

2. The portable computer security device of claim 1 wherein the flat spring is embedded in the housing.

3. The portable computer security device of claim 1 wherein the flat spring is embedded in the closing member.

4. The portable computer security device of claim 1 wherein the housing includes a first surface, a second surface and a lateral edge that joins the first surface and the second surface.

5. The portable computer security device of claim 4 wherein the flat spring extends into the lateral edge of the housing.

6. The portable computer security device of claim 4 wherein the closing member engages the lateral edge of the housing.

7. The portable computer security device of claim 4 wherein the housing includes a cover and a base such that the cover is secured to the base to form the housing.

8. The portable computer security device of claim 7 wherein the lateral edge of the housing is part of the base.

9. The portable computer security device of claim 4 wherein the lateral edge of the housing extends into the first surface and the second surface of the housing to form an indentation in the housing.

10. The portable computer security device of claim 9 wherein the flat spring extends into one portion of the lateral edge and the closing member engages another portion of the lateral edge such that the flat spring and the closing member extend across the indentation in the housing.

11. The portable computer security device of claim 10 wherein the flat spring extends into the lateral edge of the housing within the indentation in the housing.

12. The portable computer security device of claim 10 wherein the closing member engages the lateral edge of the housing within the indentation in the housing.

13. The portable computer security device of claim 10 wherein the closing member includes a planar surface that engages the lateral edge of the housing.

14. The portable computer security device of claim 1 wherein the closing member is arc-shaped.

15. The portable computer security device of claim 1 wherein the flat spring is ultrasonically inserted into the housing and the closing member.

16. The portable computer security device of claim 1 wherein the flat spring, the closing member and the housing form a carbineer style clip.

17. The portable computer security device of claim 1 wherein the flat spring is formed of tempered spring steel.
